(19) United States
(12) Patent Application Publication
(10) Pub. No.: US 2018/0075394 A1
(43) Pub. Date: Mar. 15, 2018

(54) DIGITAL PLATFORM FOR LIFE OF PLANT SERVICES

(71) Applicant: J. Ray McDermott S.A., Houston, TX (US)

(72) Inventors: Harit NAIK, Surrey (GB); Jeff STROH, Katy, TX (US); Vaseem KHAN, Sugar Land, TX (US)

(21) Appl. No.: 15/704,851

(22) Filed: Sep. 14, 2017

Related U.S. Application Data
(60) Provisional application No. 62/394,619, filed on Sep. 14, 2016.

(51) Int. Cl. G06Q 10/06; G06F 17/50; G08B 21/18

(52) U.S. Cl. CPC G06Q 10/06395; G06F 17/5004; G08B 21/18; G06Q 10/067; G06Q 10/06313

(57) ABSTRACT

In one aspect of the disclosure, a method comprises generating a model of a facility. The model includes at least: a three-dimensional structural model of the facility; a project schedule of the facility; specifications for equipment or structural components of the facility; and data received from a plurality of sensors located on the facility. The method also includes receiving additional data from the plurality of sensors located on the facility, and updating the model of the facility based on the additional data. The method further includes analyzing the updated model to determine one or more undesirable efficiency or operating issues within the facility, and generating, in response to the analyzing, an alert indicating the presence of the one more undesirable efficiency or operating issues within the facility.

### CROSS-REFERENCE TO RELATED APPLICATIONS

This application claims benefit of U.S. Provisional Application No. 62/394,619, filed Sep. 14, 2016, which is herein incorporated by reference.

### BACKGROUND

The present disclosure relates to methods of and apparatus for monitoring production equipment, such as production facilities, offshore platforms, and vessels.

### SUMMARY

In one aspect of the disclosure, a method comprises generating a model of a facility, the model including at least: a three-dimensional structural model of the facility; a project schedule of the facility; specifications for equipment or structural components of the facility; and data received from a plurality of sensors located on the facility; receiving additional data from the plurality of sensors located on the facility; updating the model of the facility based on the additional data; analyzing the updated model to determine one or more undesirable efficiency or operating issues within the facility; and generating, in response to the analyzing, an alert indicating the presence of the one more undesirable efficiency or operating issues within the facility.

In another aspect of the disclosure, a computer program product for product lifecycle management is provided. The computer program product comprises a computer-readable storage medium having computer-readable program code embodied therewith, the computer-readable program code executable by one or more computer processors to: generate a model of a facility, the model including at least: a three-dimensional structural model of the facility; a project schedule of the facility; specifications for equipment or structural components of the facility; and data received from a plurality of sensors located on the facility; receive additional data from the plurality of sensors located on the facility; update the model of the facility based on the additional data; analyze the updated model to determine one or more undesirable efficiency or operating issues within the facility; and generate, in response to the analyzing, an alert indicating the presence of the one more undesirable efficiency or operating issues within the facility.

### BRIEF DESCRIPTION OF THE SEVERAL VIEWS OF THE DRAWINGS

FIG. 1 depicts a cloud computing node according to an embodiment of the present disclosure.

FIG. 2 depicts a cloud computing environment according to an embodiment of the present disclosure.

FIG. 3 depicts abstraction model layers according to an embodiment of the present disclosure.

FIG. 4 depicts an offshore platform, according to one aspect of the disclosure.

FIG. 5 depicts a flow diagram of a method, according to one aspect of the disclosure.

### DETAILED DESCRIPTION

It is understood in advance that although this disclosure includes a detailed description on cloud computing, implementation of the teachings recited herein are not limited to a cloud computing environment. Rather, embodiments of the present disclosure are capable of being implemented in conjunction with any other type of computing environment now known or later developed.

For convenience, the Detailed Description includes the following definitions which have been derived from the “Draft NIST Working Definition of Cloud Computing” by Peter Mell and Tim Grance, dated Oct. 7, 2009.

Cloud computing is a model of service delivery for enabling convenient, on-demand network access to a shared pool of configurable computing resources (e.g. networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, tablets, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure comprising a network of interconnected nodes.

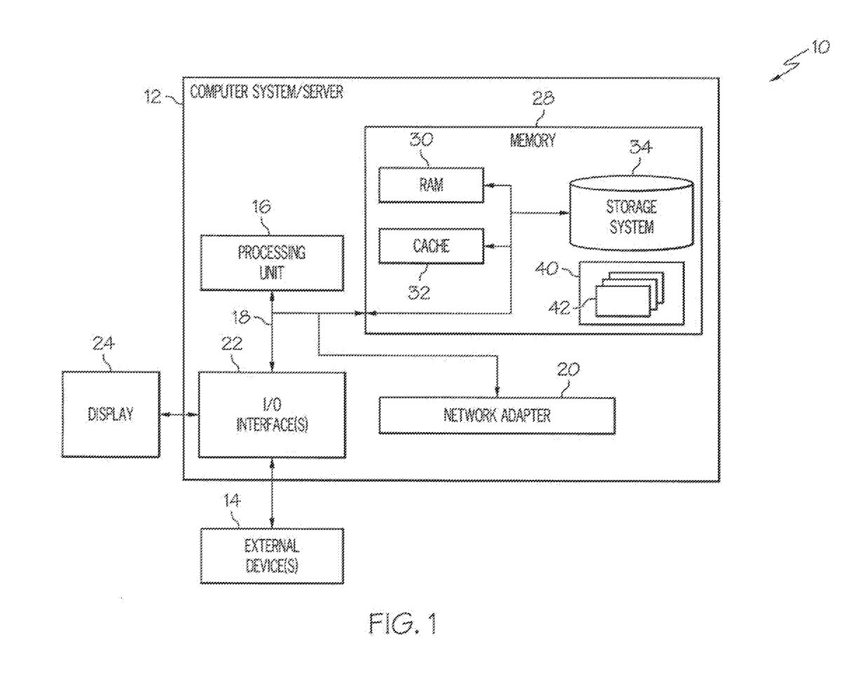

Referring now to FIG. 1, a schematic of an example of a cloud computing node is shown. Cloud computing node 10 is only one example of a suitable cloud computing node and is not intended to suggest any limitation as to the scope of use or functionality of embodiments of the disclosure described herein. Regardless, cloud computing node 10 is capable of being implemented and/or performing any of the functionality set forth hereinabove.

In cloud computing node 10 there is a computer system/server 12, which is operational with numerous other general purpose or special purpose computing system environments or configurations. Examples of well-known computing systems, environments, and/or configurations that may be suitable for use with computer system/server 12 include, but are not limited to, personal computer systems, server computer systems, thin clients, thick clients, hand-held or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 12 may be described in the general context of computer system-executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 1, computer system/server 12 in cloud computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnects (PCI) bus.

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk, and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the disclosure.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments of the disclosure as described herein.

Computer system/server 12 may also communicate with one or more external devices 14 such as a keyboard, a pointing device, a display 24, etc.; one or more devices that enable a user to interact with computer system/server 12; one or more devices, such as sensors, that provide data to the computer/server 12; and/or any devices (e.g., network card, modem, etc.) that enable computer system/server 12 to communicate with one or more other computing devices. Such communication can occur via I/O interfaces 22. Still yet, computer system/server 12 can communicate with one or more networks such as a local area network (LAN), a general wide area network (WAN), and/or a public network (e.g., the Internet) via network adapter 20 through wired or wireless connections. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, external disk drive arrays, RAID systems, tape drives, and data archival storage systems, and the like.

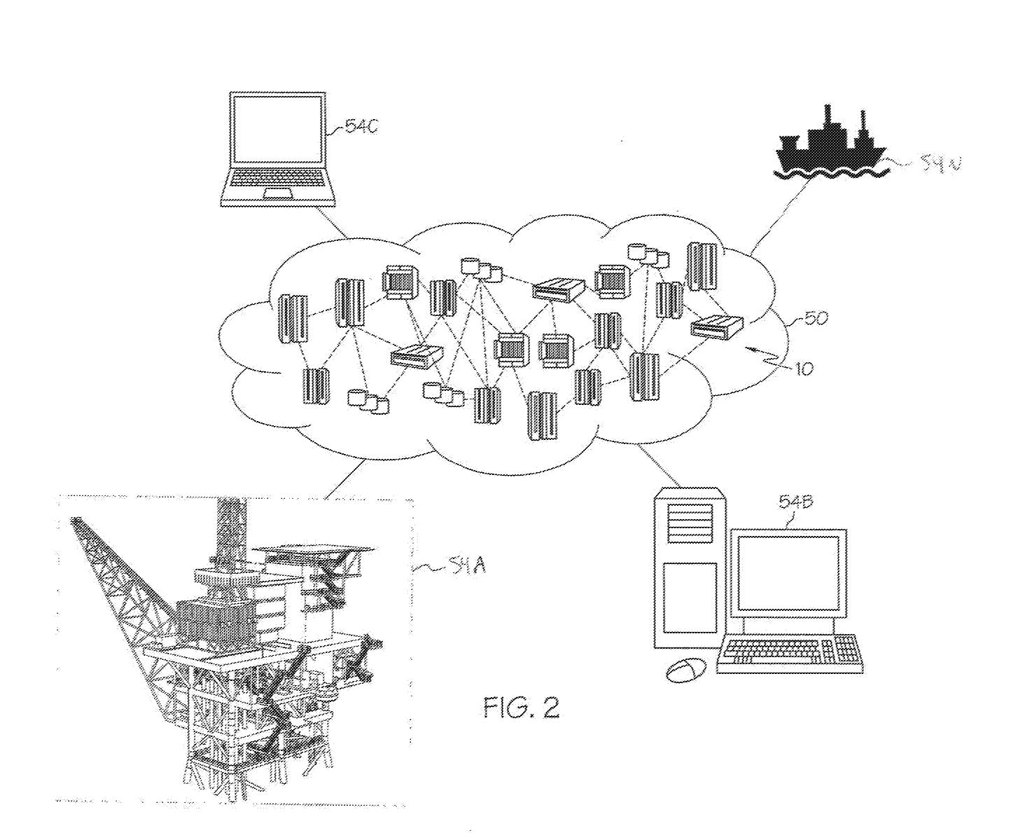

Referring now to FIG. 2, illustrative cloud computing environment 50 is depicted. As shown, cloud computing environment 50 comprises one or more cloud computing nodes 10 with which local computing devices, such as, for example, computer systems or sensors of an offshore platform 54A, a desktop computer 54B, laptop computer 54C, and/or vessel computer system 54N or sensors thereon. Nodes 10 may communicate with one another. The nodes 10 may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of devices 54A-N shown in FIG. 2 are intended to be illustrative only and that computing nodes 10 and cloud computing environment 50 can communicate with any type of computerized device over any type of network and/or network addressable connection (e.g., using a web browser).

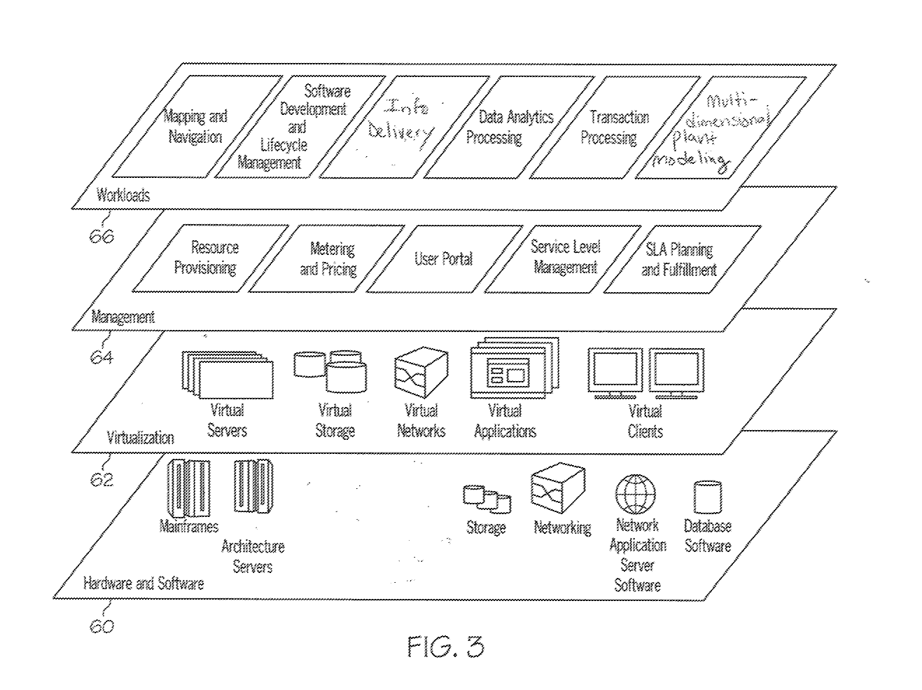

Referring now to FIG. 3, a set of functional abstraction layers provided by cloud computing environment 50 (FIG. 2) is shown. It should be understood in advance that the components, layers, and functions shown in FIG. 3 are intended to be illustrative only and embodiments of the disclosure are not limited thereto. As depicted, the following layers and corresponding functions are provided.

Hardware and software layer 60 includes hardware and software components. Examples of hardware components include mainframes, architecture based servers, storage devices, networks and networking components. Examples of software components include network application server software and database software.

Virtualization layer 62 provides an abstraction layer from which the following examples of virtual entities may be provided: virtual servers; virtual storage; virtual networks, including virtual private networks; virtual applications and operating systems; and virtual clients.

In one example, management layer 64 may provide the functions described below. Resource provisioning provides dynamic procurement of computing resources and other resources that are utilized to perform tasks within the cloud computing environment. Metering and Pricing provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal provides access to the cloud computing environment for consumers and system administrators. Service level management provides cloud computing resource allocation and management such that required service levels are met. Service Level Agreement (SLA) planning and fulfillment provides pre-arrangement for, and procurement of, cloud computing resources for which a future requirement is anticipated in accordance with an SLA.

Workloads layer 66 provides examples of functionality for which the cloud computing environment may be utilized. Examples of workloads and functions which may be provided from this layer include: mapping and navigation; software development and lifecycle management; information delivery; data analytics processing; transaction processing; and multi-dimensional plant modeling.

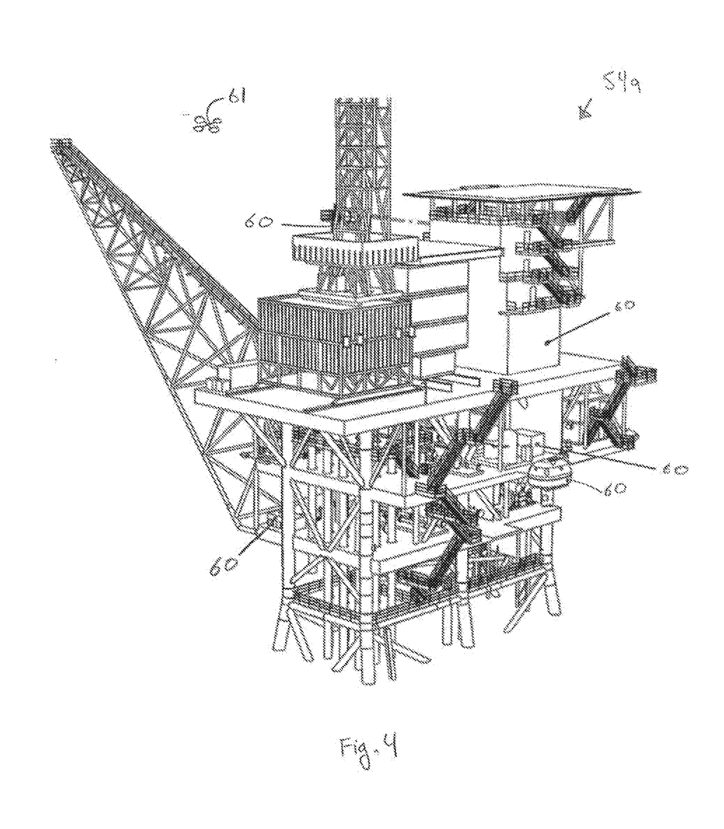

FIG. 4 depicts an offshore platform 54A, according to one aspect of the disclosure. The offshore platform 54A includes components to facilitate production of hydrocarbons. The components of the offshore platform 54A include sensors 60 operatively coupled thereto. FIG. 4 illustrates only exemplary locations of sensors 60, however, it is contemplated that as many sensors 60 as desired may be utilized. In one example, the offshore platform 54A may include hundreds or thousands of sensors 60. The sensors 60 may be coupled to equipment, hardware, structural members, and the like. Examples of sensors include sensors which indicate one or more of pressure, temperature, electrical current, weight, volume, quantity, movement, quantity, or other parameters which indicate equipment integrity, location, efficiency, useful life, and the like. It is contemplated that a drone 61 or other unmanned aerial vehicle may also be used to gather data related to the offshore platform 54A. In such an example, the drone 61 may be configured with imaging equipment, such as a camera or a thermal camera.

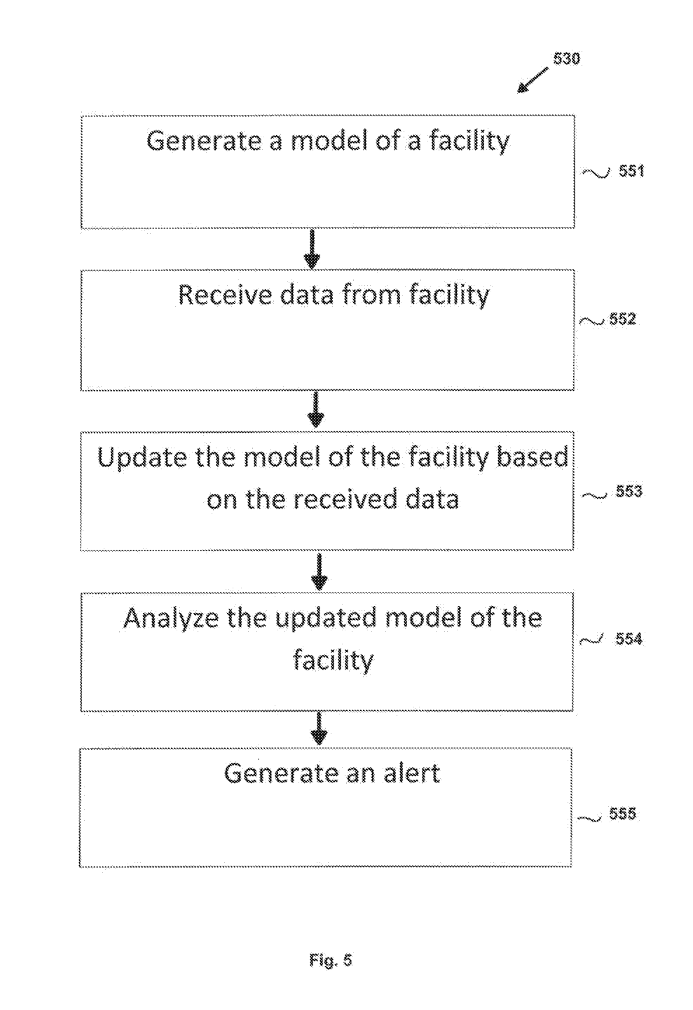

FIG. 5 depicts a flow diagram of a method 550, according to one aspect of the disclosure. The method 550 begins at operation 551. In operation 551, a model of a facility is generated. In one example, the model is a five-dimensional model or a six-dimensional (6D) model, The formation of a 6D model occurs via integration of a scheduling (or other one-dimensional documentation and data) information with a three-dimension computer model, resulting in a four-dimensional model. The four-dimensional model is updated with operational data, including data from sensors and drones, via a satellite, hardline, or other communication channel, resulting in a five-dimensional model. The five-dimensional model is subjected to data analytics, resulting in a 6D model. The data analytics include analysis and aggregation of real-time data. The 6D model is manageable from an onshore (or other remote or standalone) operations center. The facility for which the 6D model is generated, and the operations center, allows the flow of data bi-directionally, thereby allowing the 6D model to be continuously updated, and allowing the facility to receive instructions or requests from the operations center. The 6D model, and data related thereto or derived therefrom, is accessible to a user via a cloud connection. The 6D model may be generated and housed at an onshore operations center. The 5D model is similar to the 6D model, but may exclude operational data, e.g., in instances where the model is constructed before operational data is available.

In operation 552, the model is updated with data received from the facility. For example, data from the sensors located on the facility is transferred to the operations center through a cloud (or other) connection. It is contemplated that data may be continuously streamed to the operations center, or that data may be transmitted to the operations center at predetermined intervals, such as every minute, every hour, or every day. In operation 553, computer hardware at the operations center integrates the received data with the model to generate an updated model, such as an updated 6D model. The updated 6D model is accessible by users through the cloud, including from PCs and mobile devices, to instantly access up-to-date information regarding the facility.

In operation 554, the updated 6D model may be analyzed to facilitate optimization, troubleshooting, preventative maintenance, and the like, for aspects of the facility. Analysis of the updated model may be used to determine one or more undesirable efficiency or operating issues within the facility. In one example, computer algorithms may implemented to determine reductions in processing efficiency, indicating failure of equipment has occurred or is about to occur. To facilitate data analysis or rendering of recommendations, one or more of a distributed control system (DCS), process control system (PCS), a programmable logic controller (PLC) and/or the computer system operating the 6D model, may be used to analyze received dat. The DCS, PCS, PLC, and/or computer system may facilitate the collection, display, and analysis of data to a user. Additionally or alternatively, one or more computers may be tasked with the analysis of the updated 6D model.

In operation 555, an alert is generated. The alert may be provided to subscribing users, such as by text, email, or a pop-up notification on a mobile device. Additionally or alternatively, users at one or both of the facility or the operations center may receive the alert. The alert may be visual, such as a message that is displayed on a displayed, or may be an audible alert such as a horn or bell.

While aspects of the disclosure generally refer to offshore vessels and platforms, and it is contemplated that onshore equipment and facilities may similarly benefit from aspects described herein.

Benefits of the disclosure include maintaining an updated multi-dimensional model of a facility. An up-to-date model is maintained, through the reception of operational data, to facilitate maintenance and maximize facility utilization. Moreover, the collection and storage of sensor data allows for the optimization of operations and predictive maintenance of equipment. Additionally, because sensor data is analyzed in aggregate, rather than individually, a more complete picture of facility operations is obtained, thereby improving troubleshooting or maintenance. The effective use of the received sensor data reduces operating costs by about 5% and maintenance costs by about 10%.

Additionally, the received data is used to form a six-dimensional (6D) facility model, including: (1) tags, dimensions, weights, temperatures, and other defining characteristics of equipment; (2) schematic information, such as CAD or other structural design data, P&ID, electrical, plumbing, and instruments; (3) volumetric data; (4) a correspondence between three-dimensional data and facility schedule; (5) operation data, including sensor data; and (6) analyzation of receiver operational data.

It is contemplated that the 6D facility model extends the life of design and as-built data via a living and constantly updated model, through the acquisition of real-time information and the use of data analytics. The 6D facility model merges an EPC-focused PLM (product life management) platform with operational information and data analytics from a facility. As such, the 6D facility model is a living repository for maintaining updated documentation, maintenance and inspection records, operations and asset data, and provision of services such as inspection-repair-maintenance and M&O.

Moreover, the disclosed 6D platform facilities the use of augmented reality (AR) or virtual reality (VR) to interact with the 6D facility model. Interaction with a specific component of the facility through the AR or VR may allow information related to the specific component to be accessed, including documentation, maintenance history, operations history, inspection records, spare parts lists (including inventory and location), and the like. Such accessibility greatly reduces the amount of time required for a user to obtain such information, for example, instead of searching paper records. It is contemplated that the same information may be available via an electronic device using a two-dimensional display, without the use of AR or VR.

The collection and analyzation of data as described herein facilitates the display of data that indicates operational trends, thereby allowing software to identify efficiency and availability trends, and provide recommendations for improvements to such trends. Moreover, the 6D facility model is maintained onshore, at a separate location than the offshore platform 54A (or other monitored facility). The onshore maintenance of the 6D model frees up space and resources on the offshore platform 54A, and facilities the use of more powerful computing hardware. Data may be transferred from the offshore platform to an onshore location using a satellite link or other data transmission channel.

The collection and analyzation of data as described herein also facilitates management of aspects of a facility, such as an offshore platform 54A. Such aspects include engineering, operating procedures and training, personnel on board management, inspection and quality records, operations data, spare parts management, preventative maintenance, asset integrity. Data analytics of such management aspects results in process optimization, amongst other benefits.

Moreover, data flow between a facility and an onshore operations center is bidirectional, allowing issuance of instructions from the onshore operations center to the facility.

Additional benefits also include tying together data from engineering, procurement, commercial management and project management. Conventional data solutions typically only focus on a single segment of the engineering, procurement, installation, and commissioning (EPIC) of a facility, and therefore, are unable to provide a complete picture of facility performance. In contrast, disclosed embodiments integrate all aspects of EPIC, as well as post-commissioning monitoring, to provide significant improvements to maintenance and operating aspects of the facility.

The analyzation of data as described herein allows trends to be determined, thereby allowing issues to be identified before alarms are tripped or equipment failure results.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In this disclosure, reference is made to described embodiments. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present disclosure may take the form of an entirely hardware embodiment, an entirely software embodiment (including firmware, resident software, micro-code, etc.) or an embodiment combining software and hardware aspects that may all generally be referred to herein as a “circuit,” “module” or “system.”

The present disclosure may be a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, implement the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Embodiments of the disclosure may be provided to end users through a cloud computing infrastructure. Cloud computing generally refers to the provision of scalable computing resources as a service over a network. More formally, cloud computing may be defined as a computing capability that provides an abstraction between the computing resource and underlying technical architecture (e.g., servers, storage, networks), enabling convenient, on-demand network access to a shared pool of configurable computing resources that can be rapidly provisioned and released with minimal management effort or service provider interaction. Thus, cloud computing allows a user to access virtual computing resources (e.g., storage, data, applications, and even complete virtualized computing systems) in “the cloud,” without regard for the underlying physical systems (or locations of those systems) used to provide the computing resources.

Typically, cloud computing resources are provided to a user on a pay-per-use basis, where users are charged only for the computing resources actually used (e.g. an amount of storage space consumed by a user or a number of virtualized systems instantiated by the user). A user can access any of the resources that reside in the cloud at any time, and from anywhere across the Internet. In context of the present disclosure, a user may access applications, including 6D models, or related data available in the cloud. For example, the 6D model and corresponding analysis software could execute on a computing system in the cloud to facilitate facility optimization. Doing so allows a user to access this information from any computing system attached to a network connected to the cloud (e.g., the Internet).

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
generating a model of a facility, the model including at least:
a three-dimensional structural model of the facility;
a project schedule of the facility;
specifications for equipment or structural components of the facility; and
data received from a plurality of sensors located on the facility;
receiving additional data from the plurality of sensors located on the facility;
updating the model of the facility based on the additional data;
analyzing the updated model to determine one or more undesirable efficiency or operating issues within the facility; and
generating, in response to the analyzing, an alert indicating the presence of the one more undesirable efficiency or operating issues within the facility.

2. The method of claim 1, wherein the model is generated, updated, and analyzed at a location remote to the facility.

3. The method of claim 2, further comprising:
transmitting, in response to the analyzing, an instruction or message to the facility.

4. The method of claim 3, wherein the instruction or message indicates corrective action related to the one more undesirable efficiency or operating issues within the facility.

5. The method of claim 2, wherein the alert is displayed at the remote location.

6. The method of claim 2, wherein the alert is displayed at the facility.

7. The method of claim 2, wherein the alert is displayed at both the remote location and at the facility.

8. The method of claim 2, wherein receiving the additional data from the plurality of sensors located on the facility comprises transmitting data from the facility to the remote location via a satellite link.

9. The method of claim 1, wherein the updated model is configured to be interactive with a user through augmented reality of virtual reality.

10. A computer program product for product lifecycle management, the computer program product comprising:
a computer-readable storage medium having computer-readable program code embodied therewith, the computer-readable program code executable by one or more computer processors to:
generate a model of a facility, the model including at least:
a three-dimensional structural model of the facility;
a project schedule of the facility;
specifications for equipment or structural components of the facility; and
data received from a plurality of sensors located on the facility;
receive additional data from the plurality of sensors located on the facility;
update the model of the facility based on the additional data;
analyze the updated model to determine one or more undesirable efficiency or operating issues within the facility; and
generate, in response to the analyzing, an alert indicating the presence of the one more undesirable efficiency or operating issues within the facility.

11. The computer program product of claim 10, wherein the computer-readable program code is further executable to:
transmit, in response to the analyzing, an instruction or message to the facility.

12. The computer program product of claim 11, wherein the instruction or message indicates corrective action related to the one more undesirable efficiency or operating issues within the facility.
